(19) United States
(12) Patent Application Publication
(10) Pub. No.: US 2009/0023457 A1
(43) Pub. Date: Jan. 22, 2009

(54) METHOD AND SYSTEM FOR UTILIZING POSITIONAL INFORMATION OF TAGGED DATA WHEN PROCESSING INFORMATION IN WIRELESS DEVICES

(76) Inventors: Mark Buer, Gilbert, AZ (US); Thomas Quigley, Franklin, NC (US); Alexander G. MacInnis, Ann Arbor, MI (US); Arya Behzad, Poway, CA (US); Jeyhan Karaoguz, Irvine, CA (US); John Walley, Ladera Ranch, CA (US)

Correspondence Address: MCANDREWS HELD & MALLOY, LTD, 500 WEST MADISON STREET, SUITE 3400, CHICAGO, IL, 60661, US

(21) Appl. No.: 11/864,383

(22) Filed: Sep. 28, 2007

Related U.S. Application Data
(60) Provisional application No. 60/950,928, filed on Jul. 20, 2007.

(51) Int. Cl. H03J 7/32

(52) U.S. Cl. 455/456.1

(57) ABSTRACT

A Wireless mobile communication (WMC) device may be utilized to tag data generated and/or maintained in the WMC device with positional information. Positional information may comprise location and/or directional attributes. Positional attributes may be derived from operations, application, and/or accessory devices. Positional information of tagged data may be utilized to subsequently control the WMC device wherein operations may be performed and/or predicted in said WMC device based on match between current positional information of the WMC device and positional information of tagged data. User preference information and/or biometric data may be utilizing in tagging data with positional information and/or in utilizing positional data for controlling the WMC device. A remote device may be utilized for performing tagging operations, and/or storage of user preference information.

### CROSS-REFERENCE TO RELATED APPLICATIONS/INCORPORATION BY REFERENCE

This patent application makes reference to, claims priority to and claims benefit from U.S. Provisional Application Ser. No. 60/950,928 filed on Jul. 7, 2007.

The above stated application is hereby incorporated herein by reference in its entirety.

### FIELD OF THE INVENTION

Certain embodiments of the invention relate to wireless devices. More specifically, certain embodiments of the invention relate to a method and system for utilizing positional information of tagged data when processing information in wireless devices.

### BACKGROUND OF THE INVENTION

The field of wireless communication has seen dramatic growth the last few years. In today's world, most people use their wireless devices for various purposes, business and personal, on a constant and daily basis. Society is truly becoming a wireless one. A lot of wireless solutions have been introduced, and have made tremendous strides into everyday's life.

For example, the use of Wireless Personal Area Networks (WPAN) has been gaining popularity in a great number of applications because of the flexibility and convenience in connectivity they provide. WPAN systems generally replace cumbersome cabling and/or wiring used to connect peripheral devices and/or mobile terminals by providing short distance wireless links that allow connectivity within very narrow spatial limits (typically, a 10-meter range). WPAN may be based on standardized technologies, for example Class 2 Bluetooth (BT) technology. While WPAN may be very beneficial for certain applications, other applications may require larger service areas and/or capabilities.

To satisfy such needs, other technologies have been developed to provide greater wireless service. Wireless Local Area Networks (WLAN) systems may operate within a 100-meter range, for example. In contrast to the WPAN systems, WLAN provide connectivity to devices that are located within a slightly larger geographical area, such as the area covered by a building or a campus, for example. WLAN systems are generally based on specific standards, for example IEEE 802.11 standard specifications, and typically operate within a 100-meter range, and are generally utilized to supplement the communication capacity provided by traditional wired Local Area Networks (LANs) installed in the same geographic area as the WLAN system.

Other forms of wireless solutions have evolved from traditional land-based communication technologies. For example, cellular phones have become just about an absolute necessity in today's world. While cellular technology was merely intended to add an element of mobility to the traditional telephony service, this technology has grown beyond that initial purpose. Many modern cellular technologies, including such technologies as GSM/GPRS/EDGE, UMTS, and CDMA2000, incorporate substantial data capabilities. Most of today's cellular services comprise such features as text messaging, audio/video streaming, and web browsing.

Some WLAN systems may be operated in conjunction with WPAN systems to provide users with an enhanced overall functionality. For example, Bluetooth technology may be utilized to connect a laptop computer or a handheld wireless terminal to a peripheral device, such as a keyboard, mouse, headphone, and/or printer, while the laptop computer or the handheld wireless terminal is also connected to a campus-wide WLAN network through an access point (AP) located within the building. Also, cellular technology may allow use of the mobile phone as a form of wireless modem that allows connecting a laptop, for example, to the internet via a cellular network.

Devices aimed at taking advantage of the capabilities of wireless networks may be described as wireless mobile communication (WMC) devices. Today's WMC devices may comprise such devices as cellular phones, PDA's, laptops, and/or other devices.

Most WMC devices nowadays offer more than simple communicative operations. These WMC devices, in addition to providing peer-to-peer communication functions, may allow their users expansive list of personal services and utilities. Some WMC devices may enable a broad scope of gaming, scheduling, task-organizational and/or other services. Additionally, more applications that traditionally were limited to non-wireless and/or non-mobile devices may be used in conjunction with WMC devices. For example, email applications such as Microsoft Outlook® are finding their way to more WMC devices. Other applications that have gained popularity in recent years comprise audio/video applications such as still and moving picture recording application and voice recording applications. These added capabilities and/or applications are slowly turning WMC devices into indispensable on-the-move personal assistants.

However, the promising potential of WMC devices' uses beyond simple communicative operations remains stagnant because of some limitations in the devices themselves, which may include such limitations as power, storage, and/or processing. Also, while a lot of work has been put into expanding WMC devices' potential utility, not a lot of work has been put into convening these new utilities for their users. For example, while the WMC devices offer impressive array of recording, organizing, and tracking services, very little effort has been made to facilitate convenient use of data.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for utilizing positional information of tagged data when processing information in wireless devices, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram that illustrates an exemplary communication setup between a wireless mobile communication (WMC) device and a remote device, which may utilize positional tagging, in accordance with an embodiment of the invention.

FIG. 2 is a block diagram that illustrates an exemplary model for setup that includes a wireless mobile communication (WMC) device communicating directly with a remote device, which may utilize positional tagging, in accordance with an embodiment of the invention.

FIG. 3 is a block diagram illustrating a wireless mobile communication (WMC) device utilizing biometric data, in accordance with an embodiment of the invention.

FIG. 4A is a flow diagram that illustrates use of positional information in tagging data in wireless system, in accordance with an embodiment of the invention.

FIG. 4B is a flow diagram that illustrates utilizing positional information of tagged data to perform and/or predict operations in a wireless mobile communication device, in accordance with an embodiment of the invention.

### DETAILED DESCRIPTION OF THE INVENTION

Certain embodiments of the invention may be found in a method and system for utilizing positional information of tagged data when processing information in wireless devices. Wireless devices may be utilized to perform a plurality of jobs, and in doing so, the wireless devices may generate data. For example, a wireless mobile communication (WMC) device may be utilized to record a conversation or take a picture and/or capture a video clip. Subsequently, audio, video, and/or other types of multimedia data files may be generated. Various embodiments of the invention provide a mechanism, which may, for example, be utilized to capture and tag multimedia events with positional information. Positional information may comprise location and/or directional attributes. The positional information may enable identification of multimedia data files based on positional attributes without directly accessing the multimedia data files. The positional information of tagged data may be utilized to subsequently control the WMC device wherein operations may be performed and/or predicted in the WMC device based on match between current positional information of the WMC device and positional information of tagged data. Tagging operations may be performed dynamically and/or contemporaneously with generation of the multimedia data files and the tagging may be performed in the WMC device. Alternatively, a remote device may be utilized to perform tagging operations.

User preference information may enable creating and/or utilizing positional information. The user preference information may be utilized to specify positional attributes that may be utilized in creating positional information for multimedia data files. The user preference information may be maintained in the WMC device and/or externally. The user preference information may be utilized to enable the subsequent control of the WMC device based on positional information of tagged data.

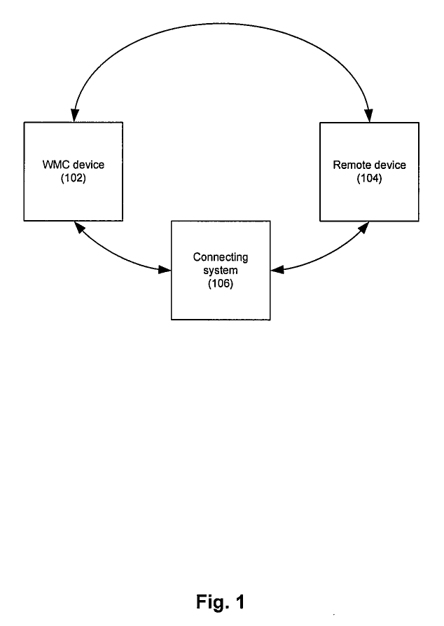

FIG. 1 is a block diagram that illustrates an exemplary communication setup between a wireless mobile communication (WMC) device and a remote device, which may utilize positional tagging, in accordance with an embodiment of the invention. Referring to FIG. 1, there is shown a wireless mobile communication (WMC) device 102, a remote device 104, and a connecting system 106.

The WMC device 102 may comprise suitable logic, circuitry and/or code that may enable performing wireless mobile communication. For example, the WMC device 102 may be utilized to perform voice, video and/or text message peer-to-peer communication. The WMC device 102 may also comprise suitable logic, circuitry and/or code that may enable performing additional functionality comprising Internet browsing, video streaming, and/or audio recording. For example, the WMC device 102 may comprise a digital camera that may enable generating sill pictures and/or video streams. Also, the WMC device 102 may comprise a microphone that may enable generating audio recordings.

The remote device 104 may comprise suitable logic, circuitry and/or code that may be enabled to communicate to with the WMC device 102. The invention may not be limited to a specific remote device, but may comprise for example, a general purpose processing device, a specialized processing device, and/or a specialized peripheral device which may be enabled to perform various jobs and/or tasks that may be requested by the WMC device 102. For example, the remote device 104 may comprise a home PC that may be more capable of performing processing and/or storage operations than the WMC device 102 due to more powerful processing subsystems and/or increased memory space compared to the WMC device 102. Such home PC may be better suited to perform processing and/or storage intensive tasks that otherwise would have to be performed in the WMC device 102. For example, where necessary and/or feasible, the WMC device 102 may utilize the remote device 104 to perform tagging of data that may have been created and/or maintained in the WMC device 102.

The connecting system 106 may comprise a plurality of interconnecting networks and suitable logic, circuitry and/or code that may be enabled to facilitate end-to-end communication between the WMC device 102 and the remote device 104. The connecting system 106 may comprise wireless and/or wired networks that may be enabled to communicate and forward messaging and/or data between the WMC device 102 and the remote device 104. The connecting system 106 may be utilized to provide a transport and/or switching fabric that may facilitate communication between the WMC device 102 and the remote device 104.

In operation, the WMC device 102 may communicate with the remote device 104 through the connecting system 106, or alternatively, where possible, the WMC device 102 may communicate directly with the remote device 104.

The WMC device 102 may be utilized for non-communicative tasks. For example, the WMC device 102 may be utilized to create video, audio, and/or other types of multimedia data files. In order to provide convenient usability of generated and/or maintained multimedia data files, the WMC device 102 may tag the multimedia data files utilizing distinguishing attributes that may enable identifying such multimedia data files and/or identifying conditions pertaining to generating and/or accessing said multimedia data files. Tagging of multimedia data files may be performed dynamically. For example, the WMC device 102 may be enabled to tag digital picture files while they are being generated or after the files have been generated.

Positional information may be utilized in performing the data tagging, and such positional information may enable identification of multimedia data files based on positional attributes that may comprise location and/or directional attributes. For example, the WMC device 102 may be enabled to tag a digital picture generated in the WMC device 102 based on positional information that may comprise, for example, the location and directional attributes of the digital picture. The location attribute may comprise information pertaining to where the digital picture was taken and/or accessed. The directional attributes may comprise spatial conditions pertaining to the generation of the digital picture, for example, azimuth, angle of view, and/or focal length. The positional attributes may be derived from operations, applications, and/or accessory devices. For example, location attributes may be derived based on Global Positioning System (GPS).

Positional information of tagged data may be utilized to subsequently control the WMC device wherein operations may be performed and/or predicted in the WMC device based on match between current positional information of the WMC device 102 and positional information associated with said tagged data. For example, a user of WMC device 102 may utilize the device to utilize the WMC device 102 to take digital pictures of sculptures in New York City. Positional information associated with tagging said digital pictures may enable the WMC device 102 to predict that the user may be interested in art-related destinations while in New York City. Consequently, when the WMC device 102 determines, based on current positional information of the WMC device 102, that the user is back in New York City, the WMC device 102 may perform internet search of art-related destinations in New York City, and display the results.

In accordance with an embodiment of the invention, user preference information may be utilized in tagging data and/or in creating and utilizing positional information. The user preference information may be utilized to specify positional attributes that may be utilized in creating positional information associated with tagging multimedia data files. For example, the user preference information may specify that focal length attributes may only be utilized with digital picture generated in the WMC device 102.

The user preference information may also be utilized to enable subsequent control of the WMC device based on positional information of tagged data. The user preference information may specify “when” a match between current positional information of the WMC device 102 with positional information associated with tagged data may be utilized to control the WMC device 102. For example, the user preference information may specify that only matches between current positional information of the WMC device 102 and positional information associated with tagged digital pictures may enable the WMC device 102 to be utilized to for the purpose of determining landmarks. The user preference information may specify “how” to determine a match between current positional information of the WMC device 102 with positional information associated with tagged data in the WMC device 102. For example, the user preference information may comprise such attributes as match-precision, which may set spatial range limitations on determining that a match between current positional information of the WMC device 102 and positional information associated with tagged data may have occurred. Where “match-precision” is set to a 100 ft, any location within 100 ft of the location attribute of the positional information associated with tagged data may constitute a positional match.

Alternatively, the user preference information may comprise information pertaining to the generation and/or access of data that may affect the use of positional information associated with tagged data. The user preference information may comprise such attributes as subject attribute which may be derived from the contents of the multimedia data file itself, or it may be derived from other applications utilized in the WMC device 102 when the multimedia file was created and/or accessed. For example, a calendar application such as Microsoft Outlook® may be utilized to determine whether a multimedia data file was generated and/or created while business or leisure activities were being performed in the WMC device 102. Consequently, controlling the WMC device 102 when there may be a match between current positional information of the WMC device 102 and positional information associated with tagged data may depend on such attributes. For example, digital pictures may be generated in the WMC device 102 while the user was in New York City on a business trip and while on vacation. Subsequently, the WMC device 102 may be controlled differently based on the determination whether the subject attribute derived via the user preference information may indicate whether the user may have returned to New York City for leisure visit or business visit.

The WMC device 102 may utilize the remote device 104 to perform operations pertaining to tagging of multimedia data files generated and/or maintained in the WMC device 102, storage of the user preference information, and/or utilizing positional information where there may be a match with current positional information of the WMC device 102. Tagging operations may be performed dynamically and/or contemporaneously in the WMC device 102 when the multimedia data files are generated and/or accessed in the WMC device 102. Alternatively, the remote device 104 may be utilized to perform tagging operations. The remote device 104 may be enabled to perform tagging of multimedia data files substantially similar to the WMC device 102 as describe hereinbefore. In such scenarios, the WMC device 102 may transfer untagged multimedia data files generated and/or accessed in the WMC device 102 to the remote device 104. The remote device 104 may generate positional information corresponding to the received multimedia data files. While user preference information may be stored directly in the WMC device 102, the user preference information may also be stored external to the WMC device 102, for example in the remote device 104. In such scenario, where the tagging operations may be performed in the WMC device 102, the WMC device 102 may retrieve the user preference information from the remote device 104 in order to perform the tagging operations.

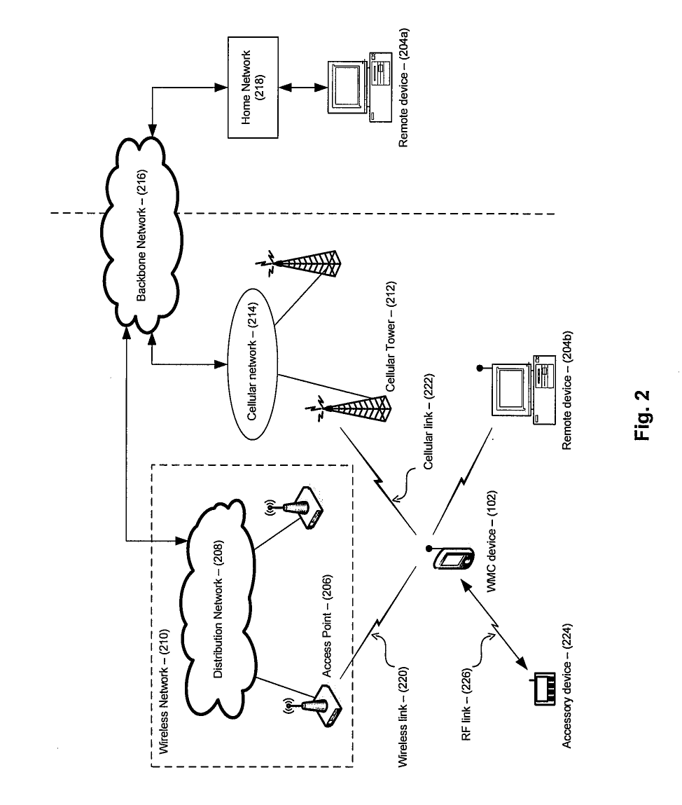

FIG. 2 is a block diagram that illustrates an exemplary model for setup that includes a wireless mobile communication (WMC) device communicating directly with a remote device, which may utilize positional tagging, in accordance with an embodiment of the invention. Referring to FIG. 2, there is shown a WMC device 102, remote devices 204a and 204b, an access point 206, a distribution network 208, a wireless network 210, a cellular tower 212, a cellular network 214, a backbone network 216, a home network 218, a wireless link 120, a cellular link 222, an accessory device 224, and a RF link 226.

The remote devices 204a and 204b may be comprises substantially similar to the remote device 104. Additionally, the remote device 204b may also comprise suitable logic, circuitry, and/or code that may enable wireless connectivity, wherein the WMC device 102 may communicate directly with the remote device 204b via a wireless connection.

The wireless network 210 may comprise a plurality of the access point 206, the distribution network 208 and suitable logic, circuitry and/or code that may enable implementing a functional block corresponding to a wireless technology. Exemplary wireless technology may comprise for example the IEEE 802.11 (WLAN) or WiMAX (IEEE 802.16) architecture. The access point 206 may comprise suitable logic, circuitry, and/or code that may be utilized to provide the necessary access infrastructure for the WMC device 102 to access the wireless network 210. The distribution network 108 may comprise suitable logic, circuitry, and/or code that may be adapted to operate as a backbone network that may be responsible for transport and link functionality for a plurality of access points in the wireless network 210.

The cellular network 214 may comprise plurality of the cellular tower 212 or base stations, and suitable logic, circuitry and/or code that may enable implementing a functional block corresponding to a cellular technology. Exemplary cellular technology may comprise cellular technologies that enable data services, including but not limited to, CDMA, WCDMA, CDMA1000, HSDPA, GSM, GPRS, EDGE, and UMTS.

The accessory device 224 may comprise suitable logic, circuitry and/or code that may enable performing some accessory functionality in conjunction with the use of the WMC device 102. For example, the accessory device may comprise a hands-free headset. The WMC device 102 may interact with the accessory device 224 over a short-range RF link 226, for example. The RF link 226 may utilize, for example, a standardized technology for inter-device short range communication. For example, the RF link 226 may correspond to a Bluetooth® connection or ZigBee connection between the accessory device 224 and the WMC device 102.

The home network 218 may comprise suitable logic, circuitry and/or code that may enable local connectivity. This local connectivity may comprise use of Local Area Network (LAN) technologies that enable data services, including but not limited to, IEEE 802.3 Ethernet. Other technologies may comprise WiMAX.

The backbone network 216 may comprise suitable logic, circuitry, and/or code that may be adapted to provide overall system connectivity between sub-networks. The backbone network 216 may be enabled to interact with, and connect different wired and/or wireless technologies. For example, the backbone network 216 may comprise a standard telephony network (POTS) that may enable data connectivity between different interface nodes linking wired and/or wireless networks comprising WLAN networks, WiMAX networks, cellular networks, and/or LAN networks.

In operation, the WMC device 102 may utilize the wireless link 220 to access the wireless network 210 via the access point 206. The WMC device 102 may also utilize the cellular link 222 to access the cellular network 214 via the cellular tower 212. The WMC device 102 may attempt to communicate with the remote device 204a via the wireless network 210 through the access point 206 and the distribution network 208. The distribution network 208 may enable forwarding messages and/or data sent from/to the WMC device 102. The backbone network 216 may enable connectivity between local networks, for example wireless network 210, and cellular network 214. Additionally the backbone network 216 may enable connectivity with the home network 218. The home network 218 may enable indirect connectivity between the WMC device 102 and remote resources. The remote device 204a may receive communication from the WMC device 102 by interacting with the backbone network 216 through the home network 218. Necessary protocol-based operations may be performed to facilitate the transmission of information through all the different components. This may comprise use of exemplary protocols such as IP, and SS7.

Once the WMC device 102 establishes connection with the remote devices 204a and/or 204b, the WMC device 102 may utilize the remote devices 204a and/or 204b in operations pertaining to tagging multimedia data files with positional information, and/or utilizing positional information to control the WMC device 102 based on match with current positional information, substantially as described in FIG. 1. The remote devices 204a and/or 204b may be utilized to perform tagging of multimedia data files generated and/or accessed in the WMC device 102. The user preference information may be stored in the remote devices 204a and/or 204b, and may be utilized in the remote devices 204a and/or 204b to enable tagging multimedia data files with positional information, and/or utilizing positional information to control the WMC device 102 based on match with current positional information of the WMC device 102. User preference information stored in remote devices 204a and/or 204b may be transferred to the WMC device 102 to enable the WMC device 102 remote devices 204a and/or 204b, substantially as described in FIG. 1. The WMC device 102 may, when necessary, determine which remote device to utilize in performing tagging operations. For example, the WMC device 102 may determine that use of the remote device 204b may require less power and/or resources because the WMC device 102 may be able to interact directly with the remote device 204b.

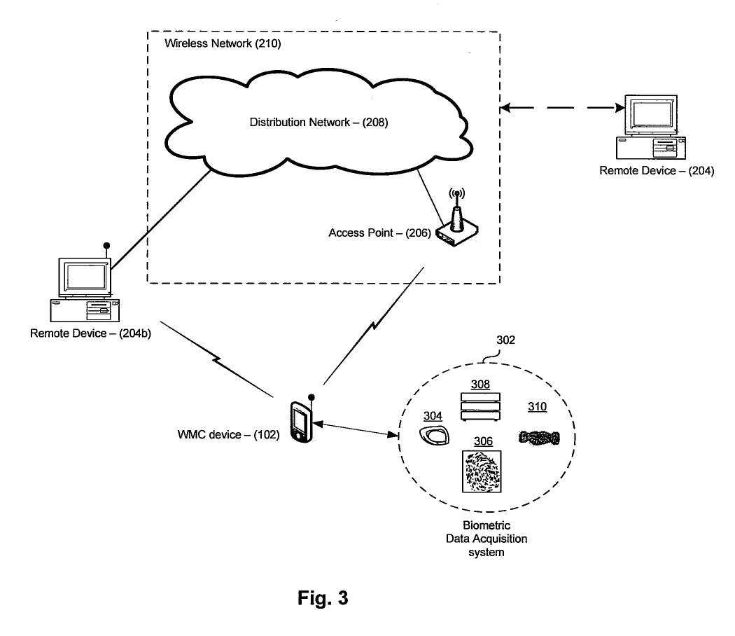

FIG. 3 is a block diagram illustrating a wireless mobile communication (WMC) device utilizing biometric data, in accordance with an embodiment of the invention. Referring to FIG. 3, there is shown the Wireless mobile communication (WMC) device 202, the access point 206, the distribution network 208, the wireless network 210, the remote device 104, the remote device 104b, and a biometric data acquisition system 302.

The biometric data acquisition system 302 may comprise a biometric sensor 304, acquired biometric data 306 (from user), a pattern recognition database 308, an authentication and validation procedure 310, and suitable logic, circuitry and/or code that may enable performing biometric validation and modification procedures. Biometric data, which may comprise finger prints, retina data, or behavioral patterns, may be unique to a person. Biometric data may be classified into two main types: physiological and behavioral biometric data. The physiological biometric data may be related to the physical aspect of the body such as facial features, finger prints, hand shape, iris blood vessel pattern (iris scan) and DNA sequences. The behavioral biometric data may be related to the expression of personality such as Electroencephalogram (EEG) that senses and measures brain wave activities, signature, hand writing and voice. Therefore the biometric data may be representative of the actual person or user.

The biometric sensor 304 may comprise suitable logic, circuitry and/or code that may enable acquiring user's biometric data in the curse of his or her use of the WMC device 102. An example of the biometric sensor 304 may be a finger print scanner, an iris scanner, hand scanner, brain wave electrodes or a voice coder. The acquired biometric data 306 may comprise biometric data acquired by the biometric sensor 304 form the user's prior use of the WMC device 102. For example, the acquired biometric data 306 may comprise the user's finger prints, iris scan, voice pattern, and/or behavioral patterns. The pattern recognition database 308 may comprise suitable logic, circuitry and/or code that may enable storing the acquired biometric data 306. The authentication and validation procedure 310 may comprise suitable logic, circuitry and/or code that may enable authenticating biometric data read during the use of the WMC device 102 by comparing the read data against the acquired biometric data 306 stored in, and retrieved from the pattern recognition database 308.

In operation, the WMC device 102 may communicate with the remote device 204b via the wireless network 210 by accessing the distribution network 208 through the access point 206. The WMC device 102 may also communicate directly with the remote device 204b over a wireless connection. Alternatively, the WMC device 102 may utilize the wireless network 210 to communicate with the wireless device 104 substantially similar to FIG. 1. Once the WMC device 102 establishes communication with remote device 204a and/or 204b, the WMC device 102 may utilize the devices for tagging multimedia data files, and/or for retrieving user preference information substantially as described in FIG. 1 and FIG. 2. The WMC device 102 and/or the remote device 204a and/or 204b may utilize context data tags for tagging multimedia data files that may be generated and/or maintained in the WMC device 102. User preference information may be utilized to tag multimedia data files wherein said user preference information may comprise preferred attributes that may be utilized in creating the context data tags. The user preference information may be stored and/or maintained in the WMC device 102 and/or the remote device 204a and/or 204b.

The biometric data acquisition system 302 may be utilized in tagging multimedia data files with positional information. Biometric data comprising physiological and/or behavior data, which may be generated via the biometric data acquisition system 302, may be utilized solely and/or in conjunction with user preference information in creating positional information for multimedia data files generated and/or maintained in the WMC device 102. For example, voice recognition techniques implement via the biometric data acquisition system 302 may enable one or more specific users of the WMC device 102 to trigger tagging of multimedia data files generated and/or maintained in the WMC device 102 with positional information. The biometric data acquisition system 302 may also be enable utilizing positional information to control the WMC device 102. For example, the WMC device 102 may utilize behavioral pattern recognition to perform and/or predict operations in the WMC device 102 when there may be a match between the current positional information of the WMC device 102 and positional information of tagged data.

Behavioral pattern recognition techniques may enable determining whether the activity performed in the WMC device 102 when the tagged data was generated may have been personal, business, or leisure in nature. Such knowledge may then be utilized in determining operations consistent with one of more of these purposes that may be performed in the WMC device 102 when there may be a positional match. For example, behavioral pattern recognition techniques may consequently determine when there may be a positional match, based on EEG readings for example, that the positional match occurred while the user of the WMC device 102 may have been engaged in business-related activities, and therefore, operations correlating to business purposes may be performed in the WMC device 102 at that time.

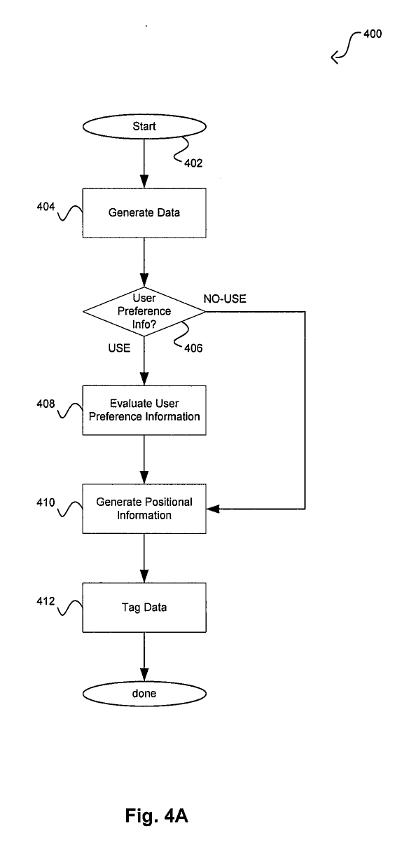

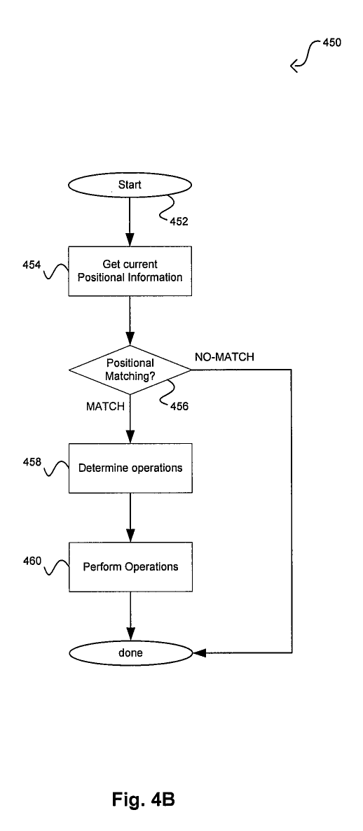

FIG. 4A is a flow diagram that illustrates use of positional information in tagging data in wireless system, in accordance with an embodiment of the invention. Referring to FIG. 4A, there is shown flow 400, representing a process of sequence of exemplary steps. In step 402, the process may commence. The WMC device 102 may be utilized for performing some task which may be a non-communicative task. For example, the WMC device 102 may be utilized substantially similar to a digital camera and/or an audio recorder. In 404, multimedia data files may be generated and/or modified in the WMC device 102 in the course of performing the task in step 402. This may comprise creating a multimedia data file, which may comprise an audio clip, a video clip, and/or digital picture. The multimedia data files may be tagged with positional information that may enable identification of the multimedia data files based on positional attributes, which may comprise location and directional attributes.

The process may then proceed to step 406. In step 406, a determination whether to use user preference information may be performed. User preference information data may be utilized to enable tagging data with positional information. In instances where the outcome of determination in step 406 indicates that user preference information may not be used, the process may proceed to step 410. The user preference information may not be utilized in the WMC device, or the user preference information may not available for tagging data with positional information.

Returning to step 406, in instances where the outcome of determination in step 406 indicates that user preference information may be used, the process may proceed to step 408. In step 408, user preference information may be evaluated. Where necessary, the user preference information may be transferred from the remote device 104. The user preference information may be utilized to specify positional attributes that may be utilized in creating positional information associated with tagging multimedia data files. For example, the user preference information may specify that focal length attributes may only be utilized with digital picture generated in the WMC device 102. In step 410, the positional information may be generated. For example, the WMC device 102 may be enabled to tag a digital picture generated in the WMC device 102 based on positional information that may comprise location and directional attributes of the digital picture. The location attribute may comprise information pertaining to where the digital picture was taken and/or accessed. The directional attributes may comprise spatial conditions pertaining to the generation of the digital picture, for example, azimuth, angle of view, and/or focal length. The positional attributes may be derived from operations, applications, and/or accessory devices. For example, location attributes may be derived based on Global Positioning System (GPS). In step 412, the data may be tagged with the positional information. A tag comprising the generated positional information may be created and utilized to mark the corresponding multimedia data file. The tag may also comprise information derived from user preference information and/or biometric data generated via the biometric data acquisition system 302. For example, the generated tag may comprise information pertaining to the nature of activities performed by user of the WMC device 102 when the data was generated in step 404. This information may be derived from user preference information based on calendar and/or scheduling information for example, and/or by utilizing behavioral recognition techniques substantially as described in FIG. 3. The tagging operations may be performed in the WMC device 102 dynamically and/or contemporaneously with the generation of data in step 404. Alternatively, the generated and/or accessed data and positional information may be transferred to the remote device 104 where the tagging operations may be performed.

FIG. 4B is a flow diagram that illustrates utilizing positional information of tagged data to perform and/or predict operations in a wireless mobile communication device, in accordance with an embodiment of the invention. Referring to FIG. 4B, there is shown flow 450, representing a process of sequence of exemplary steps. In step 452, the process may commence. The commencement of this sequence of exemplary steps may be triggered in different ways. For example, the process may be triggered by user's input, pre-selected conditions and/or condition specified in the user preference information, and/or based on biometric data derived via the biometric data acquisition system 302. In step 454, the current positional information of the WMC device 102 may be determined. The current positional information may comprise location and directional attributes of the WMC device 102. The location attribute may comprise information pertaining to where the WMC device 102 is located, while the directional attributes may comprise spatial conditions pertaining to the orientation and/or movement of the WMC device 102. The positional attributes may be derived from operations, applications, and/or accessory devices. For example, location attributes may be derived based on Global Positioning System (GPS), and directional attributes may be derived from compass-like applications. In step 456, a determination if there were a match between the current positional information of the WMC device 102 and information of tagged data may be performed. Determination of positional match may be based on match-precision that may specify acceptable deviations of exact match. Match precision may be determined based on user preference information and/or user input. In instances where the determination in step 456 indicates that there were no match between the current positional information of the WMC device 102 and positional information of tagged data, the process may terminate.

Returning to step 456, in instances where there were match between the current positional information of the WMC device 102 and positional information of tagged data, the process may proceed to step 458. In step 458, one or more operations that may be performed and/or predicted in the WMC device 102 based on the matching tagged data may be determined. For example, a positional match based on digital pictures of depicting historical landmark may enable the WMC device 102 to predict that the user may be interested in other landmarks while in the same location. Consequently, the WMC device 102 may determine that an internet search of landmarks may be performed. User preference information and/or biometric data may also be utilized in determining operations that may be performed. Where tagged data was generated for different purposes such as leisure and/or business, a determination of the nature of the activities performed in the WMC device 102 when the positional match occurred may enable selection among available operations, substantially as described in FIG. 1 and FIG. 3. In step 460, the operations determined in step 458 may be performed. The operation may be performed automatically simply based on the positional match. Alternatively, the determined one or more operations may be performed based on conditions and/or attributed specified by the user preference information, biometric data, and/or user input.

Various embodiments of the invention may comprise a method and system for utilizing positional information of tagged data when processing information in wireless devices. The WMC device 102 may be utilized to generate and/or maintain multimedia data files. The generated and/or maintained multimedia data files may be tagged with positional information that may be enable identification of said multimedia data files based on positional attributes without directly accessing the multimedia data files. Positional information may comprise location and directional attributes. Tagging operations may be performed dynamically and/or contemporaneously with the generation of the multimedia data. Tagging operation may be performed external to the WMC device 102, in the remote device 104 for example. Positional information of tagged data may be utilized to subsequently control the WMC device 102 wherein operations may be performed and/or predicted in the WMC device 102 based on a match between current positional information of the WMC device 102 and positional information of tagged data.

User preference information may enable creating and/or utilizing positional information. The user preference information may be utilized to specify positional attributes that may be utilized in creating positional information for multimedia data files. The user preference information may also be utilized to enable said subsequent control of the WMC device 102 based on positional information of tagged data by limiting use of positional information, specifying positional attributes that may be utilized in certain situations, and/or providing information that may factor into determination pertaining to control of the WMC device 102 based on the positional information. The user preference information may be maintained in the WMC device 102, or it may be stored external to the WMC device 102, in the remote device 104 for example. The precision of match between current positional information of the WMC device 102 of the positional information of tagged data may be variable, and the variation of precision of said matching may be derived from user preference information and/or user input. The tagging of data with positional information and/or utilizing positional information to control the WMC device 102 may be based on biometric data derived via the biometric data acquisition system 302.

Another embodiment of the invention may provide a machine-readable storage, having stored thereon, a computer program having at least one code section executable by a machine, thereby causing the machine to perform the steps as described herein for creating context data tags to index data in wireless system.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for handling data in wireless devices, the method comprising:
tagging data in a wireless mobile communication device with positional information utilizing user preference information while said data is being generated and/or maintained in said wireless mobile communication device; and
subsequently controlling operation of said wireless mobile communication device when current positional information of said wireless mobile communication device matches said positional information associated with said tagged data.

2. The method according to claim 1, wherein at least a portion of said user preference information is stored external to said wireless mobile communication device.

3. The method according to claim 1, comprising performing at least a portion of said tagging external to said wireless mobile communication device.

4. The method according to claim 1, comprising performing said tagging dynamically and/or contemporaneously during said generation and/or maintenance of said data.

5. The method according to claim 1, wherein said positional information comprises one or both of location and directional attributes.

6. The method according to claim 5, comprising deriving said attributes operations, applications, and/or accessory devices.

7. The method according to claim 6, wherein said operations, applications, and/or accessory devices comprise Global Positioning System (GPS).

8. The method according to claim 1, wherein said user preference information comprises calendar and/or scheduling information.

9. The method according to claim 1, comprising varying a precision of said matching of said positional information associated with said tagged data.

10. The method according to claim 9, wherein said variation of said precision of said matching is derived from said user preference information and/or user input.

11. The method according to claim 1, comprising performing said tagging of said data in said wireless mobile communication device and/or said controlling of said user wireless mobile communication device based on biometric data.

12. A machine-readable storage having stored thereon, a computer program having at least one code section for handling data in wireless devices, the at least one code section being executable by a machine for causing the machine to perform steps comprising:
tagging data in a wireless mobile communication device with positional information utilizing user preference information while said data is being generated and/or maintained in said wireless mobile communication device; and
subsequently controlling operation of said wireless mobile communication device when current positional information of said wireless mobile communication device matches said positional information associated with said tagged data.

13. The machine-readable storage according to claim 12, wherein at least a portion of said user preference information is stored external to said wireless mobile communication device.

14. The machine-readable storage according to claim 12, wherein said at least one code section comprises code for performing at least a portion of said tagging external to said wireless mobile communication device.

15. The machine-readable storage according to claim 12, wherein said at least one code section comprises code for performing said tagging dynamically and/or contemporaneously during said generation and/or maintenance of said data.

16. The machine-readable storage according to claim 11, wherein said positional information comprises one or both of location and directional attributes.

17. The machine-readable storage according to claim 16, wherein said at least one code section comprises code for deriving said attributes operations, applications, and/or accessory devices.

18. The machine-readable storage according to claim 17, wherein said operations, applications, and/or accessory devices comprise Global Positioning System (GPS).

19. The machine-readable storage according to claim 12, wherein said user preference information comprises calendar and/or scheduling information.

20. The machine-readable storage according to claim 12, wherein said at least one code section comprises code for varying a precision of said matching of said positional information associated with said tagged data.

21. The machine-readable storage according to claim 20, wherein said variation of said precision of said matching is derived from said user preference information and/or user input.

22. The machine-readable storage according to claim 12, wherein said at least one code section comprises code for performing said tagging of said data in said wireless mobile communication device and/or said controlling of said user wireless mobile communication device based on biometric data.

23. A system for handling data in wireless devices, the system comprising:
one or more processors within a wireless mobile communication device that tags data with positional information utilizing user preference information while said data is being generated and/or maintained in said wireless mobile communication device; and
said one or more processors subsequently controlling operation of said wireless mobile communication device when current positional information of said wireless mobile communication device matches said positional information associated with said tagged data.

24. The system according to claim 23, wherein at least a portion of said user preference information is stored external to said wireless mobile communication device.

25. The system according to claim 23, wherein said one or more processors performs at least a portion of said tagging external to said wireless mobile communication device.

26. The system according to claim 1, wherein said one or more processors performs said tagging dynamically and/or contemporaneously during said generation and/or maintenance of said data.

27. The system according to claim 23, wherein said positional information comprises one or both of location and directional attributes.

28. The system according to claim 27, wherein said one or more processors derives said attributes operations, applications, and/or accessory devices.

29. The system according to claim 28, wherein said operations, applications, and/or accessory devices comprise Global Positioning System (GPS).

30. The system according to claim 23, wherein said user preference information comprises calendar and/or scheduling information.

31. The system according to claim 23, wherein said one or more processors varies a precision of said matching of said positional information associated with said tagged data.

32. The system according to claim 31, wherein said variation of said precision of said matching is derived from said user preference information and/or user input.

33. The system according to claim 23, wherein said one or more processors performs said tagging of said data in said wireless mobile communication device and/or said controlling of said user wireless mobile communication device based on biometric data.
